(19) United States
(12) Patent Application Publication
(10) Pub. No.: US 2008/0311711 A1
(43) Pub. Date: Dec. 18, 2008

(54) Gapfill for metal contacts

(76) Inventors: Roland Hampp, Poughkeepsie, NY (US); Jun-Keun Kwak, Seoul-si (KR); Keith Kwong Hon Wong, Wappingers Falls, NY (US)

Correspondence Address: SLATER & MATSIL LLP, 17950 PRESTON ROAD, SUITE 1000, DALLAS, TX, 75252, US

(21) Appl. No.: 11/818,197

(22) Filed: Jun. 13, 2007

(51) Int. Cl. H01L 21/4763; H01L 21/336

(52) U.S. Cl. 438/197; 438/622; 257/E21.495; 257/E21.409

(57) ABSTRACT

A method of making a semiconductor interconnect is disclosed. A semiconductor body on which a transistor comprising a doped region is formed is provided. A dielectric region is formed over the doped region, and a contact hole is formed in the dielectric to expose the doped region. The contact hole is cleaned and a first layer of metal is formed over a bottom and sidewalls of the contact hole. The first layer of metal is thinned so that the thickness of the first layer of metal on the sidewalls is made more uniform. A barrier is formed over the first layer of metal and the contact hole is filled with conductive material.

### TECHNICAL FIELD

This invention relates generally to semiconductor devices and methods, and more particularly to devices and methods for fabricating metal interconnects.

### BACKGROUND

Semiconductor devices are used in a large number of electronic devices, such as computers, cell phones and others. One of the goals of the semiconductor industry is to continue shrinking the size and increasing the speed of individual devices. Smaller devices can operate at higher speeds since the physical distance between components is smaller. In addition, higher conductivity materials, such as copper, are replacing lower conductivity materials, such as aluminum. One challenge is to effectively fabricate small contact holes.

The shrinking of the critical dimension in semiconductor processes poses a tough challenge for front end of the line (FEOL) metal fill processes. Contacts made at the FEOL portion of the semiconductor fabrication process are used to connect interconnect at the first level of metal, typically copper, to the active areas of the device. The design rules for smaller device geometry processes, for example in 45 nm technology, require smaller contact holes with steeper sidewalls. Even with state of the art metal deposition processes, it is extremely difficult to fill the contact hole without creating a void.

A typical metal process forms tungsten plugs in the oxide level directly above the device to be connected. In order to make a good ohmic contact to the active device, layers including titanium, titanium nitride, and tungsten are consecutively deposited into the contact hole. The titanium layer on the bottom provides a good ohmic contact to the device, the titanium nitride layer protects the titanium layer from fluorine incorporated in the tungsten CVD process, and the tungsten provides most of the material which fills the contact hole. Since the first titanium layer's deposition typically has a step coverage of about 50% or less, however, the top of the contact hole develops a thicker layer of titanium than the bottom of the contact hole, thereby forming an overhang. During the subsequent chemical vapor deposition of tungsten, the top of the contact hole is prone to close before the entire contact is filled, thereby creating a void. The presence of such a void poses potential device problems such as high contact resistance and blistering. Often, during subsequent processing steps, slurries used in chemical-mechanical polishing (CMP) can get into the void causing vapor pressure to build up within the void during subsequent processing steps.

One technique to improve the filling of the contact holes is to apply an AC substrate bias to the cathode during titanium deposition. The AC substrate bias creates a more uniform application of titanium; however, the titanium is still thicker at the top of the contact hole than at the bottom of the contact hole. While the size of the voids in the contact may be reduced by using the AC substrate bias technique, the voids are not eliminated.

In the field of small, densely packed applications, using small geometry transistors, what is needed is a method and structure that can create contacts with minimal voids.

### SUMMARY OF THE INVENTION

In one embodiment of the present invention, a method of making a semiconductor interconnect is provided. A contact hole is disposed in an insulating layer which is disposed on a semiconductor body. A first layer of metal is fabricated over the semiconductor body, a portion of which is disposed over a bottom and sidewalls of the contact hole. The first layer of metal is then thinned on the sidewalls of the contact hole, whereby the thickness of the first layer of metal on the sidewalls is made more uniform.

The foregoing has outlined rather broadly features of the present invention. Additional features of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1g illustrate an embodiment process for fabricating a contact;

FIG. 2 illustrates a flowchart describing an embodiment method of fabricating a contact; and

FIGS. 3a-3c illustrate three embodiment process flow sequences through a semiconductor cluster tool.

Corresponding numerals and symbols in different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of preferred embodiments are discussed in detail below. It should be appreciated, however, that the present invention provides many applicable inventive concepts that may be embodied in a wide variety of specific contexts. The specific embodiments discussed are merely illustrative of specific ways to make and use the invention, and do not limit the scope of the invention.

The invention will now be described with respect to preferred embodiments in a specific context, namely a method for fabricating a semiconductor contact. Concepts of the invention can also be applied, however, to other electronic devices.

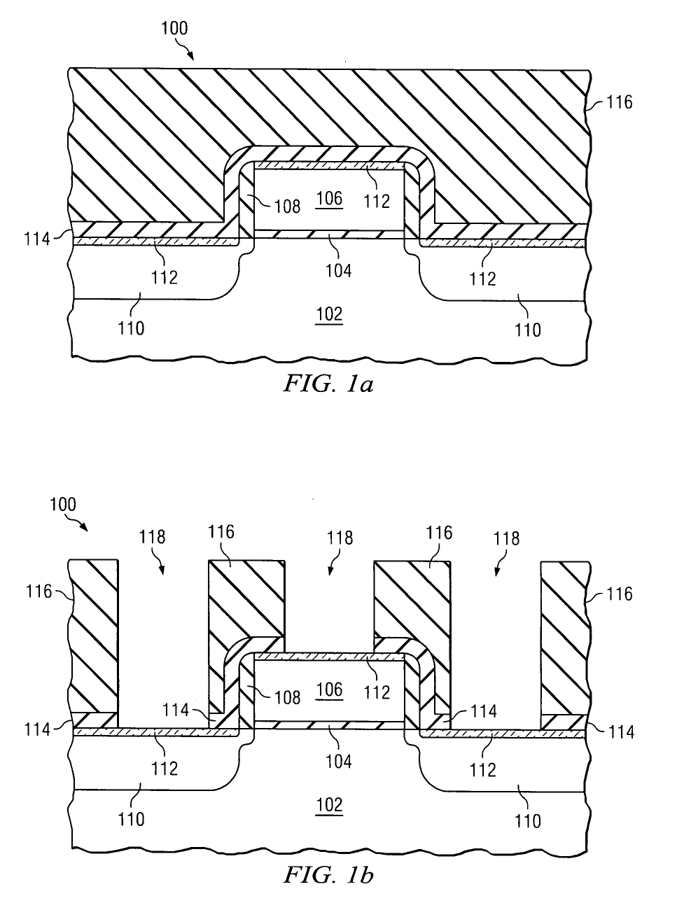

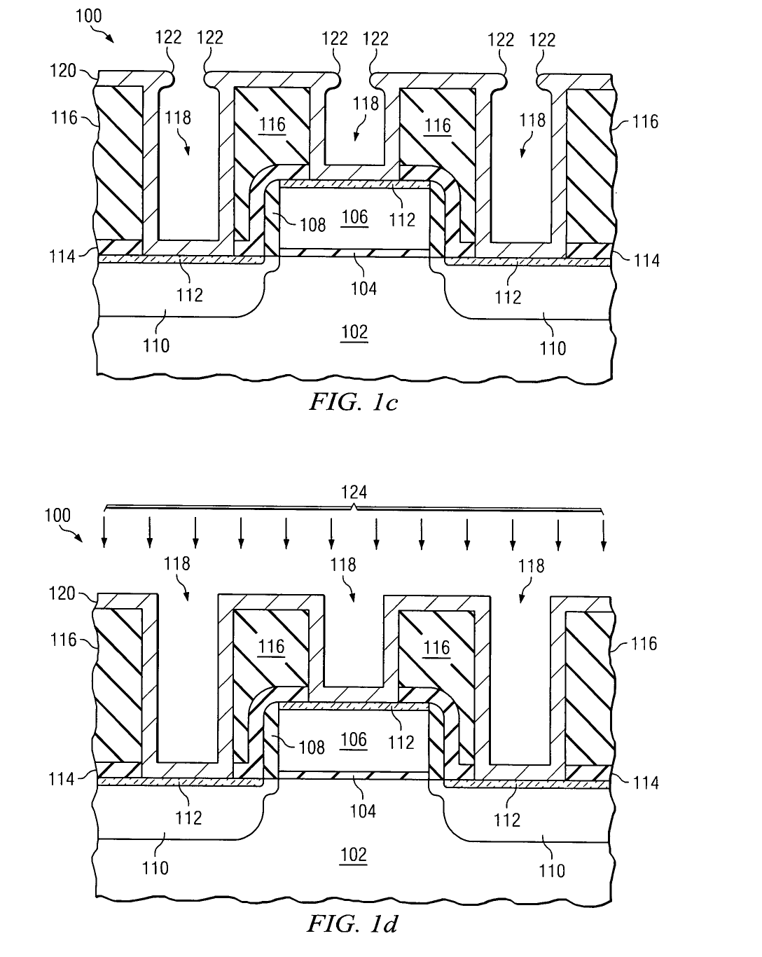

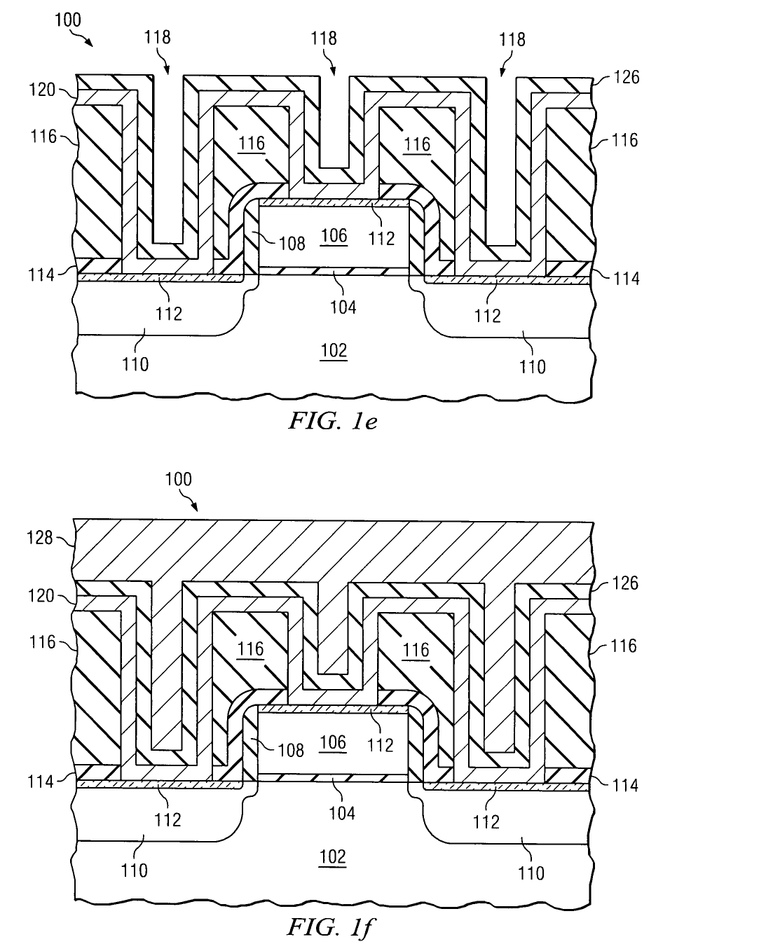

Referring first to FIG. 1a, which shows a cross section of the active area of device 100, a semiconductor body 102 is provided. A gate dielectric 104, a gate electrode 106, along with spacers 108 are formed over the semiconductor body 102.

The gate dielectric 104 may be deposited by chemical vapor deposition (CVD), thermally grown gate oxide, atomic layer deposition (ALD), metal organic chemical vapor deposition (MOCVD), physical vapor deposition (PVD), or jet vapor deposition (JVD), as examples. In other embodiments, the gate dielectric 104 may be deposited using other suitable deposition techniques. The gate dielectric 104 preferably comprises a thickness of about 10 Å to about 60 Å in one embodiment, although, alternatively, the gate dielectric 104 may comprise other dimensions.

The gate electrode 106 is formed over the gate dielectric 104. The gate electrode 106 preferably comprises a semiconductor material, such as polysilicon or amorphous silicon, although, alternatively, other semiconductor materials may be used for the gate electrode 106. In other embodiments, the gate electrode 106 may comprise TiN, HfN, TaN, W, Al, Ru, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, a partially silicided gate material, a fully silicided gate material (FUSI), other metals, and/or combinations thereof, as examples. In one embodiment, the gate electrode 106 comprises a doped polysilicon layer underlying a silicide layer (e.g., titanium silicide, nickel silicide, tantalum silicide, cobalt silicide, or platinum silicide).

The gate layer (and optionally the gate dielectric layer) are patterned and etched using known photolithography techniques to create the gate electrode 106 of the proper pattern. The combination of gate dielectric and gate electrode is commonly referred to as a “gate stack.”After formation of the gate electrodes, lightly doped source/drain regions can be implanted using the gate electrode 106 as a mask. Other implants (e.g., pocket implants, halo implants or double diffused regions) can also be performed as desired.

Spacers 108, which are formed from an insulating material such as an oxide and/or a nitride, can be formed on the sidewalls of the gate electrode 106. The spacers 108 are typically formed by the deposition of a conformal layer followed by an anisotropic etch. The process can be repeated for multiple layers, as desired.

The upper surface of device 100 is exposed to a p-type ion implant forming the heavily doped source/drain regions 110. If device 100 is a p-channel device, for example, boron ions can be implanted with a dose of about 5×10¹⁴ cm⁻² to about 5×10¹⁵ cm⁻² and an implant energy between about 1 keV and about 5 keV. In other embodiments, other materials, such as BF₂, can be implanted. If, on the other hand, device 100 is an n-channel device, an n-type ion implant is used to form the heavily doped source/drain regions 110 of the n-channel transistor. In the preferred embodiment, arsenic or phosphorus ions are implanted into the source/drain regions 110. For example, As ions can be implanted with a dose of about 1×10¹⁵ cm⁻² to about 5×10¹⁵ cm⁻² and an implant energy between about 10 keV and about 50 keV. In other embodiments, other materials, such as P, can be implanted.

Silicide regions 112 can then be formed over the source/drain regions 110, and a silicide region can be formed over the gate electrode 106 to form low resistivity upper surface regions. Silicide is formed by first depositing a silicidation metal over the source and drain regions 110 and over the gate electrode 106, then subjecting the structure to an annealing process. In the preferred embodiment, the silicidation metal is nickel, but the metal could also be cobalt, copper, molybdenum, titanium, tantalum, tungsten, erbium, zirconium, platinum, or combinations thereof. In one example, the semiconductor body 102 is then heated to about 350° C. or 450° C. to form a layer of nickel mono-silicide.

For purposes of the illustrated embodiment, a MOS device with silicided contact regions 112 is shown. In other embodiments, transistors, resistors, capacitors, or other electronic components comprising doped regions within the semiconductor body 102 requiring contact could be used. While a silicided contact region 112 is shown in FIG. 1a to represent a region from which a fabricated contact will be coupled, in other embodiments, other regions besides silicided doped regions may be provided. These regions can be unsilicided doped regions, metal regions, or dielectric regions, as an example. Furthermore, in other embodiments, contact region 112 could be the collector of a bipolar transistor, a contact of a resistor, or any other doped region requiring a metal interconnect.

A contact etch stop layer (CESL) 114 is formed over the surface of the semiconductor body 102. The CESL 114 typically consists of a nitride film (e.g., silicon nitride), but other materials can be deposited. Alternatively, in other embodiments, the CESL 114 may be omitted. An pre-metal dielectric (PMD) layer 116 is formed over the CESL 114. In a preferred embodiment of the present invention, the PMD is typically SiO₂. Alternatively, suitable PMD layers include materials such as doped glass (BPSG, PSG, BSG, USG), organo silicate glass (OSG), fluorinated silicate glass (FSG), spun-on-glass (SOG), silicon nitride, and PE plasma enhanced tetraethylorthosilane (TEOS), as examples.

Turning to FIG. 1b, photoresist (not shown) is deposited to mask off the non-exposed regions, and leave exposed regions over source/drain regions 110 and gate region 106 where contact holes 118 are to be created. The PMD 116 is then etched down to the CESL 114 using standard etch techniques, for example a reactive ion etch (RIE). In this step, the PMD 116 etches away at a faster rate than the CESL 114. Once the etch is complete, the photoresist may be removed. A second etch is then performed. This time, the CESL 114 is etched to expose the doped region 112 using the PMD 116 as a mask using standard etch techniques. In other embodiments, the CESL 114 can be eliminated.

Before contact hole 118 are filled, the semiconductor body undergoes a degas step which evaporates organic contaminants, such as volatile RIE polymer residue, and prevents them from sticking on the wafer. The degas step process is heating the wafer either by an IR light source or a hot-plate heater in an inert gas environment at 150 C.°-400° C. A wet clean can also be performed prior to the degas step in order to help remove organic contaminants.

After the degas step, a sputter pre-clean is performed which removes the majority of the native metal oxide from the silicide region on the top of the contact area 112. The wafer surface is cleaned with a bombardment of argon ions which removes, for example, about 30-60 Å of material from the exposed surfaces of the wafer. In a preferred embodiment of the present invention, the pre-clean process is a two-step process where the first step uses a more aggressive argon sputtering in order to create a tapered structure on the top edges of the contact hole. This reduces the propensity for an overhang from the subsequent titanium PVD process. In the second step, the sputter species reaches deeper into the contact hole in order to clean off oxide residue and polymers on the bottom of the contact hole.

In a preferred embodiment of the present invention, the sputter pre-clean process consists of argon sputtering in a argon sputtering chamber. Both the first and second steps use a RF bias power of between about 500 W and 600 W, and a plasma power of between 225 W and 300 W. The gas flow is preferably between about 3 sccm and 100 sccm, and the duration is between about 5 sec and 35 sec. The actual values of the first step are typically slightly higher than the second step, but the actual values are preferably optimized so that the first step creates a tapered structure on the top of the contact hole, and the second step adequately removes oxide residues and particles at the bottom of the contact hole. RF bias power, plasma power and gas flow settings are dependent on the particular semiconductor process and the processing equipment used. In alternative embodiments of the present invention, bias, plasma, and gas flow settings may be different from the ranges provided herein. In yet other embodiments of the present invention, a single step pre-clean process can be used.

As a specific example of a preferred embodiment of the present invention for use in a 45 nm to 65 nm CMOS process, the sputter pre-clean step uses a RF bias power of about 600 W, and a plasma power of about 225 W, an argon gas flow of about 15 sccm in the first step and 4 sccm in the second each step takes about 5 seconds.

As shown in FIG. 1c, a titanium layer 120 is deposited over the contact hole 118 and the PMD 116. The titanium layer provides a low ohmic contact with the silicide in the contact region 112, and is typically deposited using an Ionised Metal Plasma (IMP) PVD process to a thickness of 50-300 nm. Alternatively, in other embodiments, other metals, such as Ta, W can be used to provide a low ohmic contact to the underlying contact area.

In a preferred embodiment of the present invention, the titanium is deposited at a pressure of between 10 mT and 20 mT at a wafer temperature of between 100° C. and 200° C. The DC target power is preferably set to between 1 kW and 3 kW, the RF coil power set to between 1 kW and 3 kW, and the DC coil power set to between 1 kW and 2 kW. Preferably, an AC substrate bias is set to between 0.1 kW and 2 kW. An AC substrate bias will allow only certain species of particles with a minimum energy and vertical trajectory to hit the semiconductor wafer. All other species with less energy and at a flat angle of incidence will be prevented from hitting the wafer. A vertical trajectory for titanium particles helps to minimize any overhang. In an alternative embodiment, an AC substrate bias is not applied during titanium deposition. The gas flow in the deposition chamber is preferably set to between 15 sccm and 150 sccm.

Because the titanium IMP process typically has a step coverage of only about 50% to 55%, more titanium is deposited near the top of the contact hole 118 than is deposited near the bottom of contact holes 118. Consequently, the titanium layer 120 is thicker near the top of contact holes 118, than at the bottom of contact holes 118, thereby producing a region where the titanium forms an overhang 122 near the top of the contact holes 118.

The presence of this overhang 122 is further exacerbated by the etch characteristics of the RIE etch process that formed contact holes 118, and that tends to create bowed sidewalls. This overhang 122 is undesirable because process gases in subsequent deposition processes are restricted from entering the contact hole, as will be further described herein below. In a preferred embodiment of the present invention, the titanium deposition is performed under AC substrate bias conditions, which also helps reduce the size of the overhang by improving the conformality of the process.

Turning to FIG. 1d, a re-sputter process is performed after the titanium layer 120 is deposited. In a preferred embodiment of this invention, the surface of the semiconductor wafer is bombarded with argon ions 124, which substantially removes the titanium overhang 122, and establishes corner rounding. Corner rounding is beneficial for the fill processes in subsequent steps in order to achieve a superior gap fill. Removing overhang 122 (See FIG. 1e) makes it easier for processing gases to enter contact holes 118, thereby reducing the possibility of voids being created in the contact. In a preferred embodiment of the present invention, this re-sputter process is performed in a different chamber from the sputter pre-clean step performed prior to the titanium layer 120 deposition. During this step, some titanium will be removed from the bottom of the contact hole. The amount of titanium removed from the bottom of the contact hole will be compensated for if an AC substrate bias, which provides higher bottom coverage, is used during titanium deposition.

In a preferred embodiment of the present invention, the re-sputter process is performed with a slightly higher argon partial pressure than the pre-clean step, in order to confine the removal of the titanium to the top of the contact hole and to minimize the impact on the titanium deeper inside the contact hole. The re-sputter step is performed with a RF bias power of between 500 W to 600 W and a plasma power of between 400 W and 600 W. The gas flow in the re-sputter chamber is preferably between 10 sccm and 100 sccm. In a preferred embodiment of the present invention, an Applied Materials type PC XT or PC XTe pre-clean chamber is used. In alternative embodiments, other chamber types can be used.

In preferred embodiments, the actual process settings are optimized to maximize titanium overhang removal and minimize removal of titanium at the bottom of the contact hole. Alternatively, in another preferred embodiment of the present invention, a higher plasma power and a moderate RF bias power may be used to confine the sputtering removal to the overhanging titanium. As a specific example in a 65 nm process, a RF bias power of 600 W, a plasma power of 225 W, a gas flow of 4 sccm, and a duration of 9.4 sec is used in the pre-clean process. In the re-sputter process, however, a RF bias power of 500 W, a plasma power of 600 W, a gas flow of 15 sccm, and a duration of 6.8 sec is used. During titanium deposition, a DC target power of 2550 W, an RF coil power of 2150 W, a DC coil power of 1400 W, and AC substrate bias of 300 W, a gas flow of 35 sccm and a duration of 13.4 sec was used. It should be understood that these process settings will vary according to the process used and the dimensions of the contact hole.

A liner of titanium nitride 126 is deposited over the titanium layer 120 as shown in FIG. 1e. The titanium nitride protects the underlying titanium from the fluorine incorporated in the following tungsten deposition process. In a preferred embodiment, an MOCVD is used to deposit the titanium nitride to a thickness of between about 20 nm and 100 nm. Alternatively, in other embodiments, ALD TiN or ALD TaN can be used.

As shown in FIG. 1f, tungsten 128 is deposited over the surface of the semiconductor wafer, preferably using a WCVD process. WF₆ is typically used as a precursor. The WCVD process can typically provide a step coverage between 85-95%. As shown in FIG. 1f, the tungsten is preferably formed over the entire structure and then, as shown in FIG. 1g, removed from the upper surface of the device. The remaining portions of tungsten form the contacts or plugs. In the preferred embodiment, the tungsten is planarized using a chemical mechanical polish process. In alternate embodiments, the tungsten can be etched back, e.g., by performing a reactive ion etch (RIE).

Processing continues over the contact by depositing the upper levels of metal interconnect and the further deposition of other layers of ILD using conventional processes.

Advantages of the present invention include the ability to avoid forming voids in the resulting contact. In conventional art processes the re-sputter step described herein above and illustrated in FIG. 1d is not performed. Processing would continue without the re-sputter step and a layer of titanium nitride 126 (see FIG. 1e) would be deposited, and tungsten 128 (see FIG. 1f) would be deposited as described herein above.

Due to the physical shape of a contact hole 118 and overhang 122, and the fact that process gases are restricted from entering contact hole 118, the upper portion of contact hole 118 closes before the entire contact hole 118 is filled with material. A void is thereby formed as a result.

After the tungsten 128 deposition, a CMP process is performed which removes tungsten 128 from the surface of the wafer, ideally leaving a filled contact. During the CMP process, however, slurry used in the CMP process can get trapped in the void if the void reaches the top of the contact hole. Trapped slurries can be evaporated during subsequent processing and cause layer adhesion problems either by blistering caused by vapor pressure, or by slurry particles being left at the PMD-copper-interface. Even if the void does not reach to the top of the contact during processing, the presence of the void increases the resistance of the contact, which could adversely affect the performance of the resulting circuit.

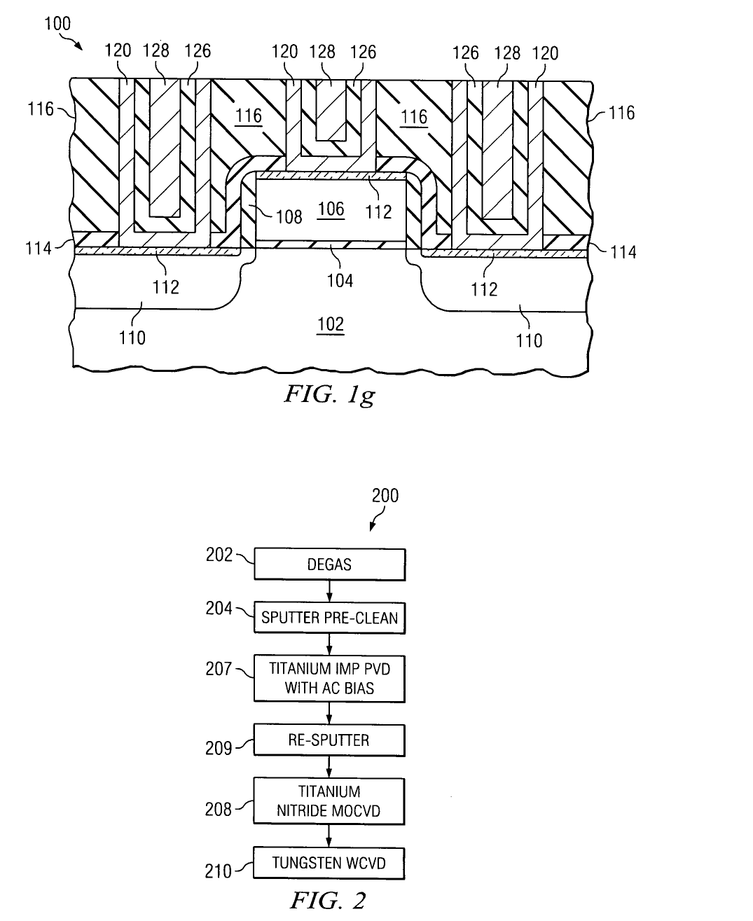

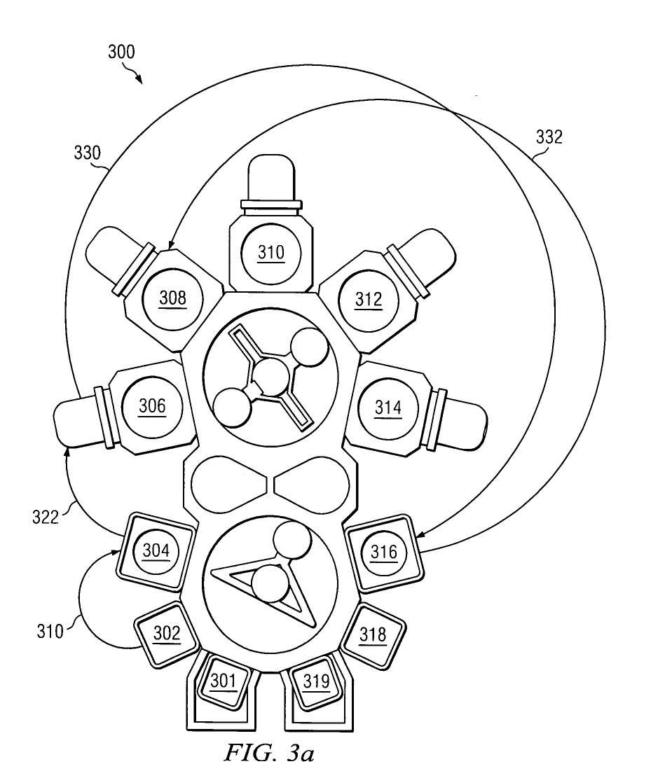

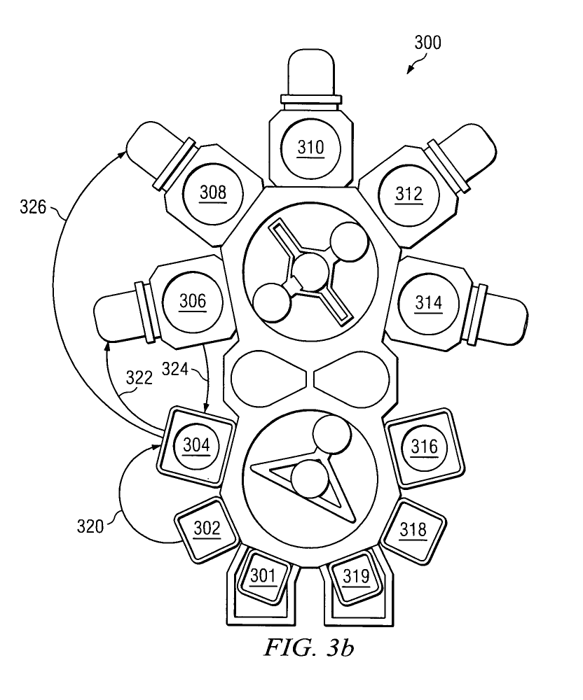

FIG. 2 shows a process flowchart of one specific embodiment of the present invention. In a preferred embodiment of the present invention, the input to the process is a semiconductor wafer that has been processed up to the point where contact holes have been etched just below the first level of metal. Alternatively, in other embodiments of the present invention, a semiconductor wafer may be provided that is being processed at upper layers of metal.

The first step 202 is a degas step described herein above, which evaporates organic contaminants on the surface of the wafer. The second step 204 is a sputter pre-clean which removes the majority of the native metal oxide from the top of a silicide layer at the bottom of the contact hole. The third step 207 is a titanium IMP PVD which deposits a layer of titanium in the contact hole and over the surface of the semiconductor wafer. In a preferred embodiment of the present invention, this titanium deposition step is performed with the AC substrate bias option switched on. Alternatively, in other embodiments, the titanium IMP PVD process is performed without an AC substrate bias.

The fourth step 209 is a re-sputter process which removes the overhang 122 from the titanium layer 120 (See FIG. 1c). In a preferred embodiment of the present invention, step 209 is preferably performed in a separate chamber from the pre-clean step 204, although in other embodiments, the same chamber is used. A separate chamber is useful in certain applications in order to avoid contamination issues and thereby to improve particle performance and yield.

The fifth step 208 is a titanium nitride deposition. Alternatively, in other embodiments, TaN can be used. The titanium nitride is deposited using an MOCVD. Alternatively, TiN or TaN can be deposited using an ALD process. After the titanium nitride deposition, step 210, a tungsten deposition is performed using a WCVD.

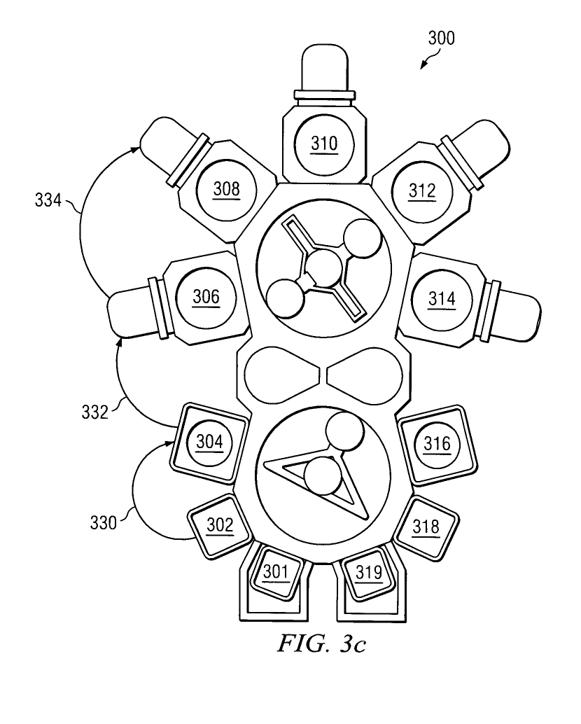

FIG. 3a shows a process flow diagram according to a preferred embodiment of the present invention. During processing, steps 1-5 are preferably performed in the same semiconductor processing cluster tool 300. Step 6 (WCVD) can also be included in the cluster tool if a WCVD chamber is attached e.g. at location 310, 312 or 314 depending on the cluster tool 300 configuration. In a preferred embodiment of the present invention, an Endura cluster tool manufactured by Applied Materials or an equivalent is used. It is advantageous to use a cluster tool because the sputter cleaned silicide layer at the bottom of the contact hole and the deposited Ti would get oxidized during wafer transfer when exposed to ambient air. The cluster tool comprises a series of chambers 301, 302, 304, 306, 308, 310, 312, 314, 316, 318, and 319, each of which is capable of performing a process step.

In a preferred embodiment of the present invention, the wafer starts processing in chamber 302 where the degas step is performed. After the degas step, the wafer is moved to chamber 304 as designated by arrow 320. In chamber 304, the pre-clean step is performed as described herein above. The wafer is then moved from chamber 304 to chamber 306 as designated by arrow 322, where the titanium deposition is performed. The wafer is then moved to chamber 316, as designated by arrow 330, for the re-sputter step. After the re-sputter step, the wafer is moved to chamber 308, as designated by arrow 332, for the titanium nitride deposition. In a preferred embodiment of the present invention, after the titanium nitride deposition, the wafer is moved to chamber 310, 312, or 314 where tungsten is deposited on the wafer if one of these chambers is configured as a WCVD chamber. In an alternative embodiment of the present invention, the wafer can be transferred to a separate tool that has a WCVD chamber, for example, a tool manufactured by Novellus, TEL, or ASML. In other embodiments of the present invention, other process sequences may be valid as long as similar processes are performed in the selected chambers.

FIG. 3b illustrates a process flow diagram of an alternate embodiment of the present invention. This embodiment is similar to the embodiment in FIG. 3a, except that after the titanium deposition in chamber 306, the wafer is moved back to chamber 304, as designated by arrow 324, for the re-sputter step. After the re-sputter step, the wafer is moved to chamber 308, as designated by arrow 326, the for the titanium nitride deposition. The process parameters for the embodiment shown in FIG. 3b are the same as they are in the embodiment shown in FIG. 3a and discussed herein above.

FIG. 3c illustrates a process flow diagram of another alternate embodiment of the present invention. In this embodiment, the wafer starts processing in chamber 302 where the degas step is performed. After the degas step, the wafer is moved to chamber 304 as designated by arrow 340. In chamber 304, the pre-clean step is performed as described herein above. The wafer is then moved from chamber 304 to chamber 306 as designated by arrow 332, where the titanium deposition is performed. After the titanium deposition, chamber 306 is purged, and the re-sputter process is performed in the same chamber 306. After the re-sputter step, the wafer is moved to chamber 308, as designated by arrow 334, for the titanium nitride deposition. In a preferred embodiment of the present invention, after the titanium nitride deposition, the wafer is moved to chamber 310, 312, or 314 where tungsten is deposited on the wafer if one of these chambers is configured as a WCVD chamber. In an alternative embodiment of the present invention, the wafer can be transferred to a separate tool that has a WCVD chamber, for example, a tool manufactured by Novellus, TEL, or ASML. In other embodiments of the present invention, other process sequences may be valid as long as similar processes are performed in the selected chambers.

In the embodiment of FIG. 3c, as a specific example, a DC target power of 2550 W, an RF coil power of 2150 W, a DC coil power of 1400 W, an AC substrate bias of 300 W, an Ar gas flow of 35 sccm, and a duration of 13.4 sec is used during the titanium deposition. After the titanium deposition, the chamber is purged for about 20 sec with an argon gas flow of about 100 sccm. After the chamber is purged, the re-sputter process takes place in the same chamber with a DC target power of between about 100 W and 250 W, preferably 150 W, and both the RF and DC power to the coil turned off. The DC target power is kept at this relatively low level to prevent sputter material from being removed from the target located on the ceiling of the chamber, while at the same time allowing for sufficient plasma to be created.

The AC substrate bias can be between about 100 W and 1000 W, preferably 500 W, AR gas flow can be between about 20 sccm and 50 sccm, and a duration of the re-sputter between about 10 sec and 20 sec. It should be understood that these process settings will vary according to the process used and the dimensions of the contact hole. In a preferred embodiment of the present invention, an Applied Materials Vectra IMP PVD chamber is used. In alternative embodiments, other chamber types can be used.

In alternative embodiment of the present invention according to the process flow diagram in FIG. 3c, the processing alternates between titanium deposition and re-sputtering for a plurality of iterations. For example, a portion of the titanium is deposited within the contact hole, followed re-sputtering, followed by another titanium deposition, and followed by another re-sputtering. Because the embodiment shown in the process flow diagram shown in FIG. 3c is such that titanium deposition and sputtering are performed in the same chamber, titanium deposition can be economically and efficiently performed in this manner. Depositing and re-sputtering in a plurality of cycles allows for a less overhang because the overhang in titanium is not given an opportunity to develop.

It will also be readily understood by those skilled in the art that materials and methods may be varied while remaining within the scope of the present invention. It is also appreciated that the present invention provides many applicable inventive concepts other than the specific contexts used to illustrate preferred embodiments. Accordingly, the appended claims are intended to include within their scope such processes, machines, manufacture, compositions of matter, means, methods, or steps.

What is claimed is:

1. A method of making a semiconductor device, the method comprising:
providing a semiconductor body;
forming a gate stack over an active area of the semiconductor body, the gate stack comprising a gate electrode disposed over a gate dielectric;
doping portions of the active area adjacent to the gate stack to form source/drain regions;
forming a dielectric region layer over the gate stack and the source/drain regions;
forming a contact hole in the dielectric layer to expose a portion of the source/drain region;
forming a first layer of metal over the semiconductor body, wherein a portion of the metal layer is disposed over a bottom and sidewalls of the contact hole;
thinning a portion of the first layer of metal on the sidewalls of the contact hole, whereby the thickness of the first layer of metal on the sidewalls is made more uniform;
forming a barrier over the first layer of metal; and
filling the contact hole with conductive metal.

2. The method of claim 1, wherein:
forming the first layer of metal comprises depositing a layer of titanium over the bottom and sidewalls of the contact hole; and
the thinning a portion of the first layer of metal comprises performing a re-sputter process.

3. The method of claim 2, wherein:
the depositing a layer of titanium comprises performing an IMP PVD; and
the re-sputter process comprises argon sputtering.

4. The method of claim 3, wherein:
the IMP PVD is performed at a pressure of between about 10 mT to 20 mT, a substrate temperature of between about 100° C. and 200° C., a DC target power between 1000 W and 3000 W, an RF coil power between about 1000 W and 3000 W, a DC coil power between about 1000 W and 2000 W, a gas flow of about 15 sccm and 150 sccm, and a duration of between about 5 seconds and 35 seconds; and
The re-sputter process is performed at a RF bias power of between about 500 W and 600 W, a plasma power of between about 400 W and 600 W, a gas flow of about 10 sccm and 150 sccm, and a duration of between about 5 seconds and 35 seconds.

5. The method of claim 4, wherein the re-sputter process RF bias power and plasma power are set to values which make the thickness of the first layer of metal on the sidewalls is made most uniform.

6. The method of claim 4, wherein the depositing a layer of titanium comprises performing an IMP PVD with an AC substrate bias.

7. The method of claim 5, wherein the AC substrate bias is between 0.1 kW and 2 kW.

8. The method of claim 1, further comprising a sputter pre-clean step before the forming of a first layer of metal.

9. The method of claim 8, wherein the sputter pre-clean step comprises argon sputtering.

10. The method of claim 8, wherein the argon sputtering is performed at a RF bias power of between about 500 W and 600 W, a plasma power of between about 225 W and 600 W, a gas flow of about 10 sccm and 150 sccm, and a duration of between about 5 seconds and 35 seconds.

11. The method of claim 9, wherein the argon sputtering is performed in a first step and a second step.

12. The method of claim 8, wherein during the first step and the second step, the argon sputtering is performed at a RF bias power of between about 500 W and 600 W, a plasma power of between about 225 W and 600 W, a gas flow of about 10 sccm and 150 sccm, and a duration of between about 5 seconds and 35 seconds.

13. The method of claim 4, further comprising a sputter pre-clean step before the forming of a first layer of metal, the sputter pre-clean step comprising an argon sputtering performed at a RF bias power of between about 500 W and 600 W, a plasma power of between about 225 W and 600 W, a gas flow of about 10 sccm and 150 sccm, and a duration of between about 5 seconds and 35 seconds.

14. The method of claim 1, further comprising forming a contact hole in the dielectric layer to expose a portion of the gate electrode.

15. The method of claim 1, wherein the barrier comprises a metal barrier film.

16. A method of making a semiconductor interconnect, the method comprising:
providing a semiconductor body;
forming a transistor over the active area of the semiconductor body, the transistor comprising a doped region.
forming a dielectric region over the doped region;
forming a contact hole in the dielectric to expose a portion of the doped region;
cleaning the contact hole;
forming a first layer of metal over the semiconductor body, wherein a portion of the metal layer is disposed over a bottom and sidewalls of the contact hole;
thinning a portion of the first layer of metal on the sidewalls of the contact hole, whereby the thickness of the first layer of metal on the sidewalls is made more uniform;
forming a barrier over the first layer of metal; and
filling the contact hole with conductive metal.

17. The method of claim 16, wherein:
the cleaning the contact hole comprises a sputter pre-clean;
the forming a first layer of metal comprises depositing a layer of titanium over the bottom and sidewalls of the contact hole;
the thinning the portion of the first layer of metal comprises a re-sputter process;
the forming the barrier comprises forming a titanium nitride barrier; and
the filling the contact hole comprises filling the contact hole with tungsten.

18. The method of claim 17, wherein:
the sputter pre-clean comprises argon sputtering;
the depositing a layer of titanium comprises performing an IMP PVD;
the re-sputter process comprises argon sputtering;
the forming of the titanium nitride barrier comprises performing an MOCVD; and
the filling the contact hole with tungsten comprises performing a WCVD.

19. The method of claim 18, wherein:
the pre-clean process is performed at a RF bias power of between about 500 W and 600 W, a plasma power of between about 225 W and 600 W, a gas flow of about 10 sccm and 150 sccm, and a duration of between about 5 seconds and 35 seconds.
the IMP PVD is performed at a pressure of between about 10 mT to 20 mT, a wafer temperature of between about 10° C. and 200° C., a DC target power between 1000 W and 3000 W, an RF coil power between about 1000 W and 3000 W, a DC coil power between about 1000 W and 2000 W, a gas flow of about 15 sccm and 150 sccm, and a duration of between about 5 seconds and 35 seconds; and
the re-sputter process is performed at a RF bias power of between about 500 W and 600 W, a plasma power of between about 225 W and 600 W, a gas flow of about 10 sccm and 150 sccm, and a duration of between about 5 seconds and 35 seconds.

20. The method of claim 18, wherein the pre-clean step comprises two pre-clean steps.

21. The method of claim 16, further comprising performing a degas step prior to performing the sputter pre-clean.

22. The method of claim 21, wherein the degas step comprises heating the wafer to a temperature between 150° C. and 400° C.

23. The method of claim 21, wherein the degas step is performed in an inert gas environment and wherein the heat source is an IR light or a hot-plate heater.

24. The method of claim 16, further comprising performing a CMP on the surface of the semiconductor body.

25. A method for fabricating a semiconductor wafer, the method comprising:
providing a semiconductor wafer comprising a layer of oxide in which a contact hole has been fabricated;
performing a degas step on the semiconductor wafer;
performing a sputter pre-clean on the semiconductor wafer after the degas step;
depositing a layer of titanium on the semiconductor wafer after the sputter pre-clean, the depositing a layer of titanium being performed under AC substrate bias conditions;
performing a re-sputter step on the semiconductor wafer after the depositing the layer of titanium;
depositing a layer of titanium nitride on the layer of titanium after the re-sputter process; and
depositing a layer of tungsten on the layer of titanium nitride.

26. The method of claim 25, wherein the degas step, the sputter pre-clean, the depositing the layer of titanium, the re-sputter step, and the depositing the layer of titanium nitride are all performed on the same cluster tool.

27. The method of claim 25, wherein the degas step, the sputter pre-clean, the depositing the layer of titanium, the re-sputter step, the depositing the layer of titanium nitride, and the depositing of the tungsten are all performed on the same cluster tool.

28. The method of claim 26, wherein:
the degas step is performed in a first chamber of the cluster tool;
the sputter pre-clean is performed in a second chamber of the cluster tool;
the depositing the layer of titanium is performed in a third chamber of the cluster tool;
the re-sputter step is performed in the second chamber of the cluster tool; and
the depositing the layer of titanium nitride is performed in a fourth chamber of the cluster tool.

29. The method of claim 26, wherein:
the degas step is performed in a first chamber of the cluster tool;
the sputter pre-clean is performed in a second chamber of the cluster tool;
the depositing of the layer of titanium is performed in a third chamber of the cluster tool;
the re-sputter step is performed in a fourth chamber of the cluster tool; and
the depositing the layer of titanium nitride is performed in a fifth chamber of the cluster tool.

30. The method of claim 27, wherein:
the degas step in the first chamber comprises removing organic contaminants sticking on the surface of the semiconductor wafer;
the sputter pre-clean in the second chamber comprises removing a majority of a native metal oxide disposed on top of a layer of silicide disposed at a bottom of the contact hole;
the depositing the layer of titanium performed in the third chamber comprises an IMP PVD, wherein the AC bias conditions comprise an AC substrate bias;
the re-sputter step in the fourth chamber comprises process wherein the layer of titanium is made thinner on sidewalls of the contact hole near the top of the contact hole; and
the depositing the layer of titanium nitride in the fifth chamber comprises a MOCVD.

31. The method of claim 30, wherein:
the depositing the layer of titanium comprises a IMP PVD, the IMP PVD performed at a pressure of between about 10 mT to 20 mT, a wafer temperature of between about 10° C. and 200° C., a DC target power between 1000 W and 3000 W, an RF coil power between about 1000 W and 3000 W, a DC coil power between about 1000 W and 2000 W, an AC substrate bias power of between about 100 W and 2000 W, a gas flow of about 15 sccm and 150 sccm, and a duration of between about 5 seconds and 35 seconds; and
the re-sputter process is performed at a RF bias power of between about 400 W and 600 W, a gas flow of between about 10 sccm and 150 sccm, and a duration of between about 5 seconds and 35 seconds.

32. The method of claim 29, wherein the depositing the layer of tungsten is performed in a sixth chamber of the cluster tool, and wherein the depositing the layer of tungsten comprises a WCVD.

33. The method of claim 26, wherein:
the degas step is performed in a first chamber of the cluster tool;
the sputter pre-clean is performed in a second chamber of the cluster tool;
the depositing the layer of titanium is performed in a third chamber of the cluster tool;
the re-sputter step is performed in the third chamber of the cluster tool; and
the depositing the layer of titanium nitride is performed in a fourth chamber of the cluster tool.

34. The method of claim 33, wherein the depositing of the titanium is performed in a plurality of steps, and wherein the re-sputter step is performed in a plurality of steps.

35. The method of claim 34, wherein each depositing step alternates in sequence with a re-sputter step.

36. The method of claim 34, wherein each depositing step deposits a portion of a total amount of titanium deposited.

37. The method of claim 33, wherein:
the depositing the layer of titanium comprises a IMP PVD, the IMP PVD performed at a pressure of between about 10 mT to 20 mT, a wafer temperature of between about 100° C. and 200° C., a DC target power between 1000 W and 3000 W, an RF coil power between about 1000 W and 3000 W, a DC coil power between about 1000 W and 2000 W, an AC substrate bias power of between about 100 W and 1000 W, a gas flow of about 15 sccm and 150 sccm, and a duration of between about 5 seconds and 35 seconds; and
the re-sputter process is performed at a DC target power of between about 100 W and 250 W, an AC substrate bias power of between about 100 W and 1000 W, a gas flow of between about 10 sccm and 150 sccm, and a duration of between about 5 seconds and 35 seconds.

38. The method of claim 37 further comprising a purge step after the depositing of the titanium and the re-sputter process, wherein the purge step is performed with a gas flow of between about 10 sccm and 150 sccm, and a duration of between about 5 seconds and 35 seconds.

39. The method of claim 37, wherein the depositing the layer of tungsten is performed in a fifth chamber of the cluster tool, and wherein the depositing the layer of tungsten comprises a WCVD.
